(19) United States
(12) Patent Application Publication
(10) Pub. No.: US 2008/0087969 A1
(43) Pub. Date: Apr. 17, 2008

(54) PLANAR-TYPE SEMICONDUCTOR DEVICE AND METHOD OF MANUFACTURING THE SAME

(76) Inventor: Yong-Keon Choi, Gyeonggi-do (KR)

Correspondence Address: SHERR & NOURSE, PLLC, 620 HERNDON PARKWAY, SUITE 200, HERNDON, VA, 20170, US

(21) Appl. No.: 11/865,482

(22) Filed: Oct. 1, 2007

(30) Foreign Application Priority Data
Oct. 11, 2006 (KR) 10-2006-0098762

(51) Int. Cl. H01L 29/78; H01L 21/336

(52) U.S. Cl. 257/409; 438/289; 257/E29.256; 257/E21.409

(57) ABSTRACT

A planar-type semiconductor device including a plurality of device isolation areas defining an active area formed over a semiconductor substrate; at least one drift area formed in the semiconductor substrate; a well region formed in the semiconductor substrate; a gate pattern formed over the semiconductor substrate and between the plurality of device isolation areas; a pair of source regions and a drain area formed in the semiconductor substrate adjacent sides of the gate pattern; at least one drift region formed in the well region; a drain region formed in the drift region; and a silicide layer formed over the source regions, the drain region, and partially over the gate pattern.

The present application claims priority under 35 U.S.C. 119 to Korean Patent Application No. 10-2006-0098762 (filed on Oct. 11, 2006), which is hereby incorporated by reference in its entirety.

### BACKGROUND

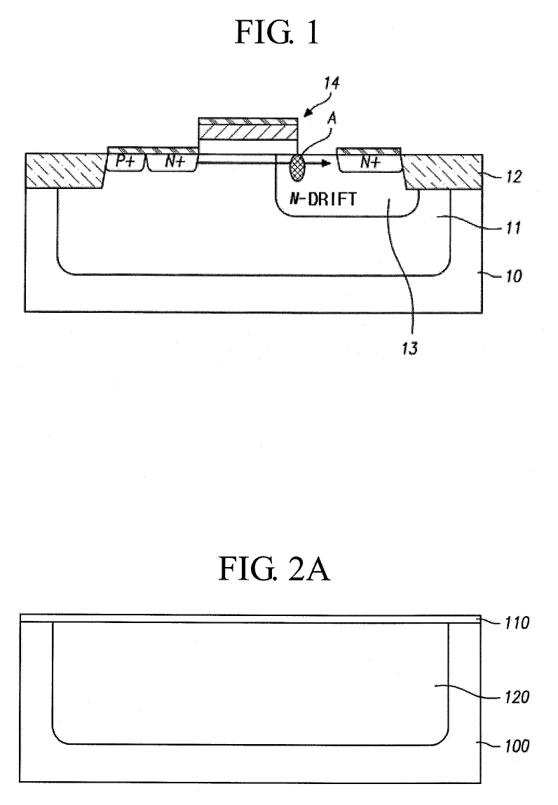

As illustrated in example FIG. 1, a planar-type semiconductor device may be arranged as a high voltage CMOS device, including semiconductor substrate 10, well region 11, device isolating layers 12, expanded drift region 13 and gate 14 provided on and/or over semiconductor substrate 10. Expanded drift region 13 may be un-silicided in order to obtain a high breakdown voltage.

Such a structure, however, has disadvantages. For instance, the generation of impact ionization a high electric field “A” applied to an edge portion of gate 14 edge cannot be suppressed. Accordingly, the edge portion of gate 14 may be fragile in view of the reliability of breakdown voltage. In essence, in such high voltage CMOS devices, since gate 14 may be applied with a high voltage in the drain region, the gate electric field direction from gate 14 to the drain may be altered in a portion where the largest electric field is generated and the portion of the drain region of the gate edge in view of current flow. Consequently, gate 14 may be fragile when subject to an electric field such that fluctuations of voltage and current can indispensably be caused when driving gate 14.

### SUMMARY

Embodiments relate to a planar-type semiconductor device and a method of manufacturing the same that enhances the reliability of breakdown voltage by reducing a high electric field applied to an edge area of a gate on the drain side.

Embodiments relate to a method of manufacturing a planar-type semiconductor device including at least one of the following steps. Forming a well region on and/or over a semiconductor substrate. Forming a plurality of shallow trench isolation regions (STI) on and/or over the semiconductor substrate. Forming at least one drift region by implanting dopant into one side or both sides of the well region. Forming a gate pattern by sequentially forming and patterning a gate oxide film and a polysilicon layer on and/or over the semiconductor substrate including the STIs. Forming a source region and a drain region by implanting the dopant into the semiconductor substrate at both sides of the gate pattern. Forming a silicide blocking mask on and/or over the drift region, including the one side of the polysilicon layer of the gate pattern. Performing a silicide process using the silicide blocking mask.

Embodiments relate to a planar-type semiconductor device including: a well region formed on and/or over a semiconductor substrate; a plurality of STIs formed on and/or over the semiconductor substrate; at least one drift region formed by implanting dopant into one side or both sides of the well region; a gate pattern formed by sequentially forming and patterning a gate oxide film and a polysilicon layer on and/or over the semiconductor substrate including the STIs; a source region and drain region formed by implanting a dopant into the semiconductor substrate at both sides of the gate pattern; a silicide blocking mask formed on and/or over the drift region, including the one side of the polysilicon layer of the gate pattern; and a silicide layer formed on and/or over the source region.

### DRAWINGS

Example FIG. 1 illustrates impact ionization generated in a planar-type semiconductor device.

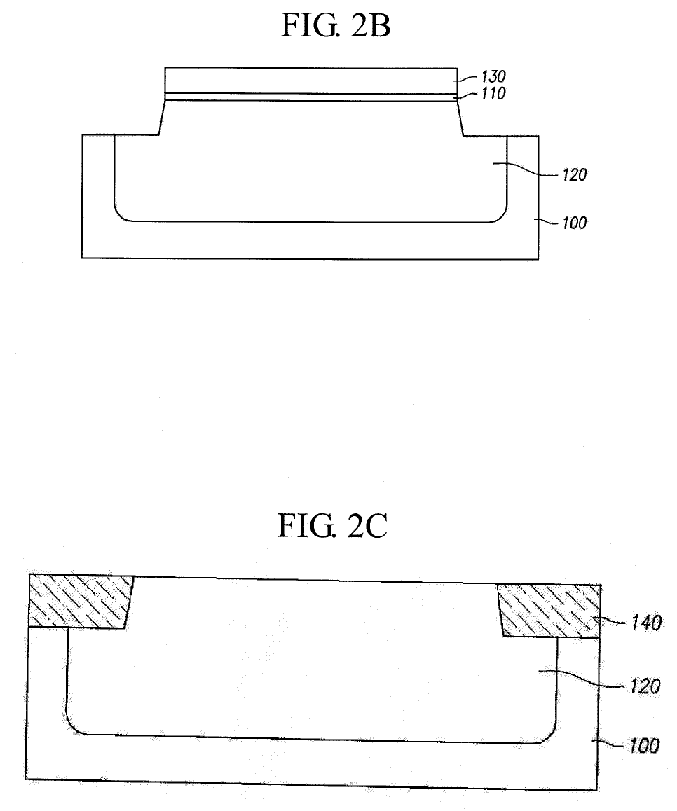

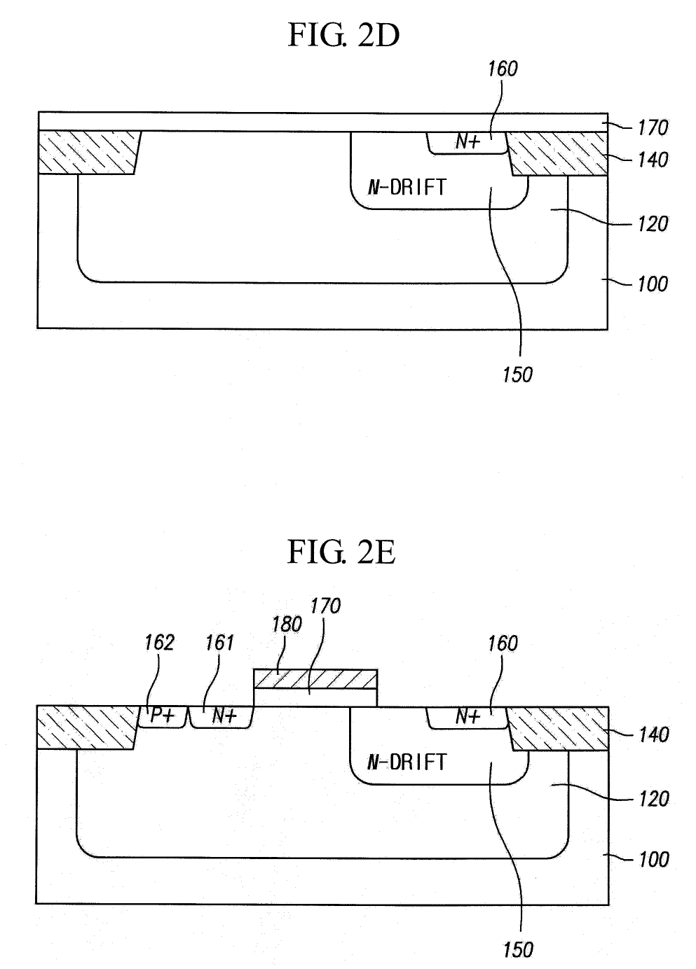

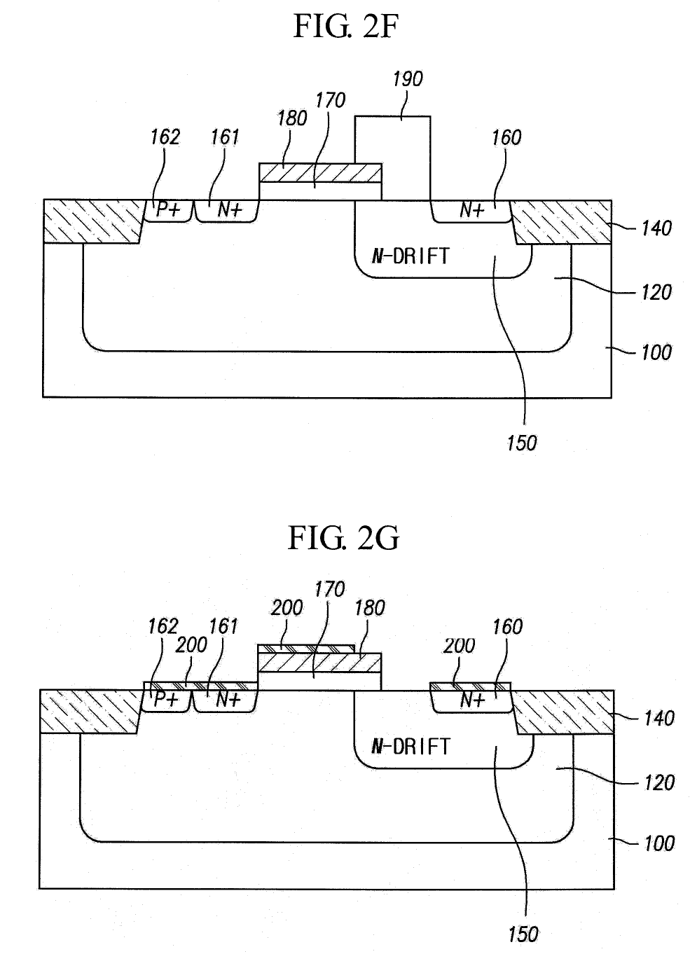

Example FIGS. 2A to 2G illustrate a method of manufacturing a planar-type semiconductor device, in accordance with embodiments.

### DESCRIPTION

As illustrated in example FIG. 2A, in accordance with embodiments, a planar-type semiconductor device can include oxide film 110 formed on and/or over semiconductor substrate 100. Well area 120, for example, an HP-well can be formed in semiconductor substrate 100 by implanting an impurity thereto. Well-area 120 can be formed having an HN-well.

As illustrated in example FIG. 2B, a plurality of device isolating layers such as shallow trench isolations (STIs) 140 defining an active area can be formed in semiconductor substrate 100 by forming photoresist pattern 130 on and/or over an area of substrate 100 where STIs 140 will not be formed and a plurality of trenches can be formed by etching photo resist pattern 130.

As illustrated in example FIG. 2C, the trench can be buried with an oxide such as SiO₂ and the like to form STI 140.

As illustrated in example FIG. 2D, after formation of STIs 140, oxide film 110 can be removed. The uppermost surface of well 120 not including STIs 140 can be implanted with an N-type dopant to form N-drift area 150. The N-type dopant can be implanted in high concentrations in an uppermost surface area of N-drift region 150 provided adjacent to STIs 140 to form N+-type drain region 160. Thereafter, gate oxide film 170 can be formed on and/or over the surface of substrate 100 including device isolating layers 140. Gate oxide film 170 can also be formed using a thermal oxidation process whereby gate oxide film 170 is not formed on and/or over the uppermost surface of STIs 140.

N-drift area 150 can be formed at a deeper depth than N+-type source region 161 and P+-type source region 162 in order that they can be formed asymmetrical or symmetrical to each other.

As illustrated in example FIG. 2E, polysilicon layer 180 can be formed on and/or over gate oxide film 170 and then patterned to form a gate pattern. The gate pattern can be formed across an active area defined by device isolating layers 140.

As illustrated in example FIG. 2F, silicide blocking mask 190 can then be formed on and/or over a portion of the uppermost surface of polysilicon layer 180 and also a portion of the uppermost surface of N-drift region 150. Silicide blocking mask 190 can have a thickness of 1000 Angstrom and can be formed as a stacked film composed of a silicon oxide film such as a plasma enhanced-tetra ethylene ortho silicate (PETEOS) and the like, a silicon nitride film such as SiN and the like, and a silicon oxynitride (SiON) film. Alternatively, silicide blocking mask 190 can have a thickness of 1000 Angstrom and can be formed as a stacked film composed of at least any one of the silicon oxide film, the silicon nitride film, and the silicon oxynitride (SiON) film. An antireflection film can be selectively formed beneath or on and/or over silicide blocking mask 190. Silicide blocking mask 190 can be formed so as to overlap N-drift region 150 and polysilicon layer 180 and to conform to the boundary of N-drift region 150. Silicide blocking mask 190 can be formed to contact drain area 160.

As illustrated in example FIG. 2F, subsequently, a silicide process can be performed using silicide blocking mask 190 and removing silicide blocking mask 190 so that silicide layer 200 is formed on and/or over drain region 160, N+-type source region 161 and P+-type source region 162 and polysilicon layer 180. Silicide layer 200 can be composed of a metal, such as any one of titanium (Ti), cobalt (Co), and nickel (Ni) using a self-aligned silicide method. Silicide layer 200 can alternatively be formed on and/or over polysilicon layer 180 so as not to overlap N-drift region 150 and polysilicon layer 180 but adjacent the edge of N-drift region 150.

An un-silicide process can be performed on and/or over polysilicon of the gate pattern overlapping N-drift region 150. Therefore, the electric field at the lower area of the gate is relieved by the resistance of the polysilicon 180 while also not being vertically directed and thus, may be dispersed in several directions.

Silicide blocking mask 190 can be configured to not overlap N-drift region 150 on and/or over polysilicon layer 180 of the gate pattern without requiring an additional process in partially performing the partial un-silicide in order that a drain edge of a gate poly in high voltage planar-type semiconductor devices is partially un-silicided. Accordingly, it can be possible to enhance the reliability of breakdown voltage of the high voltage CMOS device.

In accordance with embodiments, the drain edge of the gate poly in the planar-type semiconductor device can be partially un-silicided to make it possible to enhance the reliability of breakdown voltage of the HV CMOS device.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a well region in a semiconductor substrate;
forming a plurality of device isolation areas in the semiconductor substrate;
forming at least one drift region in the semiconductor substrate;
forming a gate pattern by sequentially forming and patterning a gate oxide film and a polysilicon layer over the semiconductor substrate;
forming in the semiconductor substrate at both sides of the gate pattern a first source region of a P+type, a second source region of an N+-type, and a drain region of an N+-type;
forming a silicide blocking mask partially over an exposed surface of the drift region and a portion of the uppermost surface of the polysilicon layer; and then forming a silicide layer by performing a silicide process using the silicide blocking mask.

2. The method of claim 1, wherein the silicide blocking mask comprises a laminate film.

3. The method of claim 2, wherein the laminate film comprises a silicon oxide film, a silicon nitride film, and a silicon oxynitride film.

4. The method of claim 1, wherein the silicide blocking mask comprises at least one of a silicon oxide film, a silicon nitride film, and a silicon oxynitride (SiON) film.

5. The method of claim 1, wherein the silicide blocking mask comprises a plasma enhanced-tetra ethylene ortho silicate.

6. The method of claim 1, further comprising forming an antireflection film over and beneath the silicide blocking mask.

7. The method of claim 1, further comprising forming an antireflection film beneath the silicide blocking mask.

8. The method of claim 1, wherein the silicide process comprises a self-aligned silicide process.

9. The method of claim 8, wherein the silicide layer comprises at least one of titanium, cobalt, and nickel.

10. The method of claim 1, wherein the plurality of device isolation areas comprise shallow trench isolations.

11. The method of claim 1, wherein the at least one drift area is formed by implanting a dopant into at least one side of the well area.

12. The method of claim 1, wherein forming the at least one drift region comprises implanting a portion of the well region with an N-type dopant.

13. The method of claim 1, wherein forming the drain region comprises implanting in high concentrations of an N-type dopant in a portion of the drift region.

14. An apparatus comprising:
a semiconductor substrate;
a plurality of device isolation areas defining an active area formed in the semiconductor substrate;
at least one drift area formed in the semiconductor substrate;
a well region formed in the semiconductor substrate;
a gate pattern formed over the semiconductor substrate and between the plurality of device isolation areas;
a pair of source regions and a drain area formed in the semiconductor substrate adjacent sides of the gate pattern;
at least one drift region formed in the well region;
a drain region formed in the drift region; and
a silicide layer formed over the source regions, the drain region, and partially over the gate pattern.

15. The apparatus of claim 14, wherein the silicide layer formed on the gate pattern is formed outside the drift area with being contacted with the boundary of the drift.

16. The apparatus of claim 14, wherein the silicide layer is formed using a self-aligned silicide process.

17. The apparatus of claim 16, wherein the silicide layer comprises at least one of titanium, cobalt, and nickel

18. The apparatus of claim 14, wherein the gate pattern comprises a gate oxide film and a polysilicon layer.

19. The apparatus of claim 14, wherein the pair of source regions comprises a P+-type source region and an N+-type source region.

20. A method comprising:
forming a well region in a semiconductor substrate;
forming a plurality of device isolation areas in the semiconductor substrate;
forming a drift region in the semiconductor substrate;
forming a gate pattern over the semiconductor substrate and partially over the drift region;
forming a P+-type source region and an N+-type source region adjacent the gate pattern and a drain region in a portion of the drift region; and then forming a silicide layer over the P+-type source region, the N+-type source region, the drain region, and partially over the uppermost surface of the gate pattern.
